(19) United States
(12) Patent Application Publication
(10) Pub. No.: US 2006/0190201 A1
(43) Pub. Date: Aug. 24, 2006

(54) Derivation of composite step-function response

(76) Inventor: Xiaofen Chen, West Linn, OR (US)

Correspondence Address: TEKTRONIX, INC., MS 50-LAW, P.O. BOX 500, BEAVERTON, OR, 97077, US

(21) Appl. No.: 11/399,740

(22) Filed: Apr. 7, 2006

Related U.S. Application Data
(63) Continuation of application No. 09/933,605, filed on Aug. 20, 2001, now abandoned.

(51) Int. Cl. G01R 23/00

(52) U.S. Cl. 702/75

(57) ABSTRACT

A method of deriving a composite step function response from a band-limited transmission channel frequency response includes the steps of obtaining a time domain response from the band limited frequency response, identifying reflection events from the time domain response, estimating an impulse response from the identified reflection events, and determining the composite step function from the estimated impulse response. The impulse response estimation is obtained from the observed time domain response as
y(n)=h(n)−h(n)\hat{×}w(n) where y(n) is the observed time domain response, h(n) is the impulse response to be estimated and w(n) is a window function
w(n)=sin(ω₀*n/Fₛ)πn

where ω₀ is the initial frequency and Fₛ is the sample rate frequency. For reduction in calculation expense an impulse response segment is calculated over a narrow range of data about each reflection event. The resulting estimated impulse response is accumulated to produce the composite step response for the band limited transmission channel.

### CROSS-REFERENCES

This application is a continuation of prior application Ser. No. 09/933,605, filed Aug. 20, 2001.

### BACKGROUND OF THE INVENTION

The present invention relates to distance to fault measurements, and more particularly to the derivation of a composite step-function response from band-limited channel frequency response in distance to fault (DTF) measurements.

For time domain reflectrometry (TDR) or distance to fault (DTF) transmission channel tests, step function testing along with impulse testing is often used to measure wave propagation and reflections of the transmission channel. The step-function test is useful when the transmission discontinuity is frequency selective. Due to its time domain integration nature, the step function response is more sensitive to low frequency components. In measuring frequency response of a system the measured frequency range may be band limited, such as between 25 MHz and 2.5 GHz.

Referring to FIGS. 1a, 1b and 1c the respective graphs show the impulse response, the step function response, and a band limited step function response for a particular transmission channel. As readily seen, the step function response is very important in transmission channel diagnosis since the impulse response produces an almost insignificant difference where the reflection or discontinuity is a low frequency response, i.e., reflects low frequencies rather than high frequencies, while the step function produces a very noticeable difference as it contains mostly d.c. and low frequency components.

Generally the step function response may be derived by integrating the impulse response. As indicated above due to its integration nature, the step function response is more sensitive to low frequency components. For a frequency domain instrument, a transmission channel reflection coefficient is measured at each specified frequency within a specified range of frequencies, i.e., the measurement is band limited. TDR or DTF measurements are derived from the inverse Fourier transform (FFT⁻¹) of the channel reflection coefficient response. When a frequency domain instrument cannot make measurements at low frequencies, i.e., the source covers a frequency range that excludes the low frequencies, an incorrect step function response may be produced when the band-limited TDR response is integrated, as shown in FIG. 1c, especially if the discontinuity or reflection is low frequency selective.

What is desired is a method of deriving a composite step function response from a band-limited transmission channel response obtained from frequency domain measurements.

### BRIEF SUMMARY OF THE INVENTION

Accordingly the present invention provides a method of deriving a composite step function response from a band-limited transmission channel frequency response. The method includes the steps of obtaining a time domain response from the band limited frequency response, identifying reflection events from the time domain response, estimating an impulse response from the identified reflection events, and determining the composite step function from the estimated impulse response. The impulse response estimation is obtained from the observed time domain response as
y(n)=h(n)−h(n)\hat{×}w(n)
where y(n) is the observed time domain response, h(n) is the impulse response to be estimated and w(n) is a window function
w(n)=sin(ω₀*n/Fₛ)/πn
where ω₀ is the initial frequency and Fₛ is the sample rate frequency. For reduction in calculation expense an impulse response segment is calculated over a narrow range of data about each reflection event. The resulting estimated impulse response is accumulated to produce the composite step response for the band limited transmission channel.

The objects, advantages and other novel features of the present invention are apparent from the following detailed description when read in conjunction with the appended claims and attached drawing.

### BRIEF DESCRIPTION OF THE SEVERAL VIEWS OF THE DRAWING

FIGS. 1a, 1b and 1c are graphical views respectively of (a) an impulse response, (b) a step function response and (c) a band limited step function response for a transmission channel according to the prior art.

FIG. 2 is a graphical illustration view in the frequency domain of an estimated transmission channel impulse response algorithm according to the present invention.

FIG. 3 is a graphical illustration view in the time domain of the estimated transmission channel impulse response algorithm according to the present invention.

FIG. 4 is a plan view of a display of the composite step function in the band limited transmission channel according to the present invention.

### DETAILED DESCRIPTION OF THE INVENTION

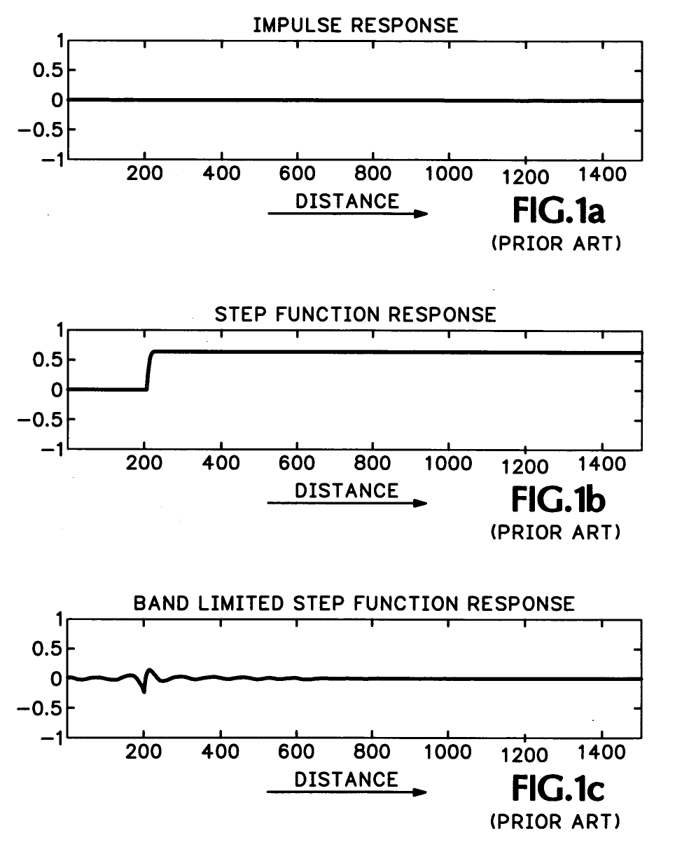

Referring to FIG. 1c it is apparent that the band limited step function response does not give a true step function response to the discontinuity event or reflection that exists at that point. Therefore in order to provide an accurate step function it is necessary to estimate the transmission channel impulse response. The step function response derivation, as described below, has four steps: distance to fault derivation from band limited channel response; reflection surface detection or identification, impulse response estimation and step function response calculation.

Distance to fault (DTF) is derived from reflection coefficients measured at discrete frequencies over a band limited frequency range. For computational efficiency and accuracy the following process is used, as an example:

For B being the measurement bandwidth and Fᵤ the upper frequency edge, then a working bandwidth B_{w}, is
U=└Fᵤ/B┘ and B_{w}=Fᵤ/U
A new central frequency becomes F_{c}=Fᵤ−B_{w}/2
and the lower frequency edge is Fₗ=Fu−B_{w}.

Down shift the frequency band [Fₗ, Fᵤ] to baseband (F_{c}=0) and perform inverse discrete Fourier transform (IDFT or DFT⁻¹) using sample rate Fₛ equal to 2B_{w}. This is equivalent to directly performing IDFT on frequency data. Then up-convert to frequency F₀=B_{w}/2 and extract the real part of the signal as the DTF signal.

In the digital domain this process may be simplified by letting H(ωₖ) be a reflection coefficient at frequency ωₖ (k=0, 1, . . . , N−1), ω₀=2πFₗ and ω_{N-1}=2πFᵤ. Then
h(n)=(1/N)Σ_{k=0→N-1}H(ωₖ)e^{i2π(k/2N)n}=IDFT(2H,2N)
h_{DTF}=Re(h(n))
H(ω₀)=0, . . . , H(ωₘ₋₁)=0 where m=(Fᵤ−B)N/B_{w}.
The reflection surface identification may be automatic or user-interactive. In user-interactive mode a user inputs a center location (i₁+i₂)/2 or the edges of the impulse response. In the automatic mode the center location is detected based on the event's reflection magnitude in the time domain. A detection function A(n) may be an envelope value of the up-converted signal h(n)
A(n)=|h(n)|
Alternatively using the local energy of the baseband signal as the detection function,
x(n)=|h(n)|sign(h_{c}(n)), A(n)=Σ_{m=-K→K}×(n−m)
where h(n)=h_{c}(n)+jhₛ(n). In either case if |A(n)| is greater than a threshold, then a reflection surface is detected and the center location determined.

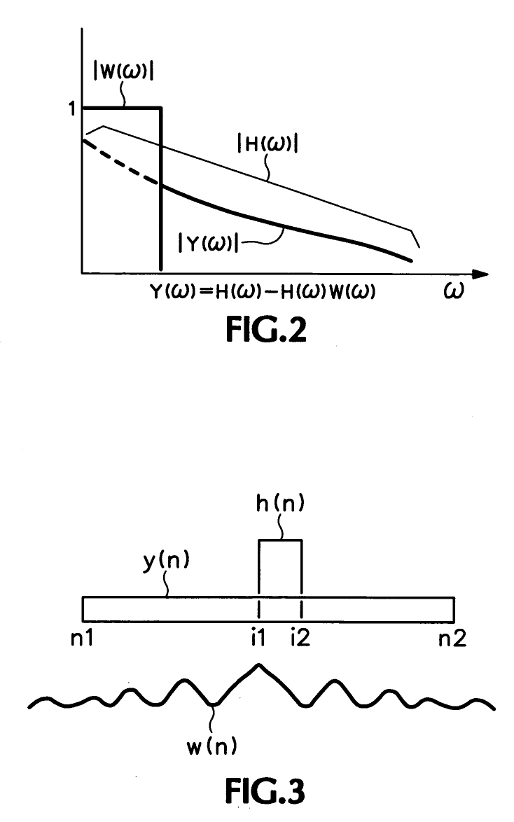

For impulse response estimation let h(n) denote the impulse response to be estimated and y(n) the corresponding band limited response (y(n)=h_{DTF}(n)). Looking at FIG. 2 in the frequency domain Y(ω)=H(ω)−H(ω)W(ω), where Y(ω) represents the band limited frequency coefficients, W(ω) is a window function representing the frequency range not covered by the band limited source and H(ω) is the combination of the measured frequency coefficients and the frequency coefficients estimated over the window. In the time domain this becomes
y(n)=h(n)−h(n)\hat{×}w(n)=h(n)−Σₘh(m)w(n−m)
the window function being w(n)=sin(ω₀n/Fₛ)/πn where Fₛ is the sampling frequency. As seen, the observed time response y(n) is a linear function of the impulse response h(n). Since y(n) may have many data points, it may be computationally expensive if every impulse response point is estimated. However normally each reflection surface covers a very short distance and its response lasts a limited time. Therefore for each identified reflection surface the impulse response is estimated over a narrow range of data around the reflection surface, as illustrated in FIG. 3.
n₁≦n<i₁
−Σ_{m=i1→iM}h(m)w(n−m)
i₂<n≦n₂
y(n)=h(n)−Σ_{m=i1→iM}h(m)w(n−m) i₁≦n≦i₂
In matrix form this is

$$\vert \begin{matrix}y ( {n}_{1} ) \\ ⋮ \\ y ( {i}_{1} - 1 ) \\ y ( {i}_{1} ) \\ y ( {i}_{1} + 1 ) \\ ⋮ \\ y ( {i}_{2} ) \\ ⋮ \\ y ( {n}_{2} )\end{matrix} \vert \vert \begin{matrix}- w ( {n}_{1} - {i}_{1} ) & - w ( {n}_{1} + 1 - {i}_{1} ) & … & - w ( {n}_{1} + M - 1 - {i}_{1} ) \\ ⋮ & & & \\ - w ( - 1 ) & - w ( - 2 ) & … & - w ( - M ) \\ 1 - w ( 0 ) & - w ( - 1 ) & … & - w ( 1 - M ) \\ - w ( 1 ) & 1 d - w ( 0 ) & … & - w ( 2 - M ) \\ ⋮ & ⋮ & & ⋮ \\ - w ( {i}_{2} - {i}_{1} ) & - w ( {i}_{2} - {i}_{1} - 1 ) & … & 1 - w ( 0 ) \\ ⋮ & ⋮ & & ⋮ \\ - w ( {n}_{2} - {i}_{1} ) & - w ( {n}_{2} - {i}_{1} - 1 ) & … & - w ( {n}_{2} - {i}_{2} )\end{matrix} \vert \vert \begin{matrix}h ( {m}_{1} ) \\ h ( {m}_{2} ) \\ ⋮ \\ h ( {m}_{M} )\end{matrix} \vert$$

The localized h(m) may be optimally resolved by applying least-square error criteria.
Y=DH, H=(D^{T}D)⁻¹D^{T}Y

The final step function response is calculated by accumulating the impulse response.
x(n)=h(n)\hat{×}u(n)=Σ_{m=-∞→∞}h(n−m)u(m)
where u(n) is the step function

$$u ( n ) = \begin{matrix}1 & n \geq 0 \\ 0 & n < 0\end{matrix}$$

This produces
x(n)=Σ_{m=0→n}h(n−m)

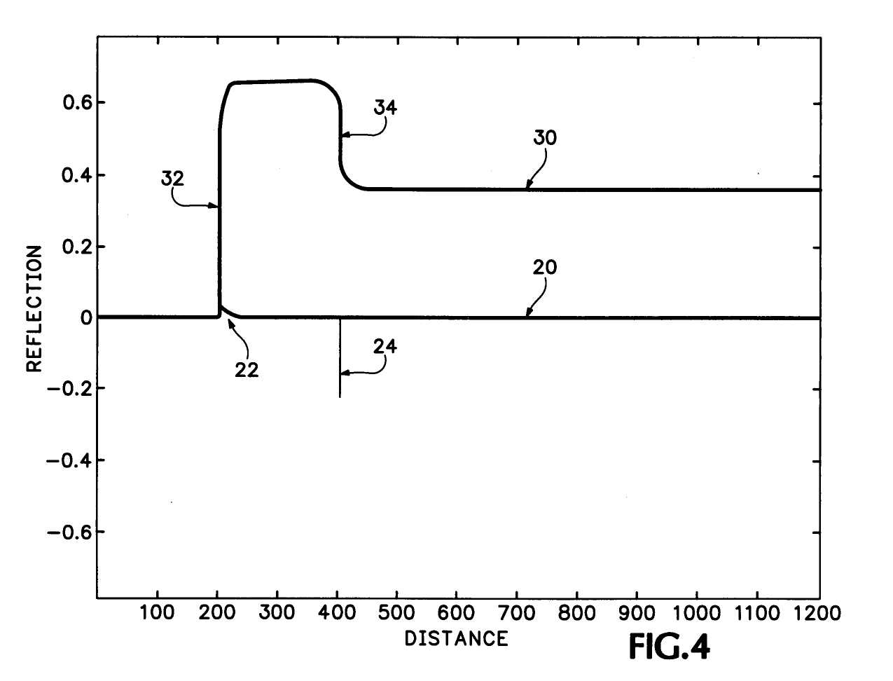

Typical results of the band limited method described above are shown in FIG. 4 which shows the estimated impulse and step function responses of a band limited channel. The lighter line represents the estimated impulse response 20, showing an apparent small reflection 22 at approximately 200 meters and a larger negative impulse 24 at approximately 400 meters. The corresponding step function response 30 shows a significant response 32 at 200 meters and a less significant response 34 at 400 meters. The combination of these responses gives a more complete picture of the events that occur in the transmission channel.

Thus the present invention provides a method of deriving a composite step function response from a band limited transmission channel frequency response in distance to fault measurement by estimating the impulse response from the measured frequency response and a window for the excluded frequencies, and accumulating the impulse response to obtain the step function response.

What is claimed is:

1. A method of deriving a step function response for a transmission channel having a band limited frequency response comprising the steps of:
deriving a distance-to-fault (DTF) signal from the band limited frequency response;
estimating an impulse response as a function of the DTF signal and a window function; and
accumulating the impulse response to produce the step function response.

2. The method as recited in claim 1 wherein the deriving step comprises the steps of:
downshifting the frequency band of the band limited frequency response to baseband to produce a baseband signal;
performing an inverse Fourier transform on the baseband signal to produce a time domain signal;
upconverting the time domain signal to produce a complex time domain signal; and
extracting the DTF signal from the complex time domain signal.

3. The method as recited in claim 1 wherein the deriving step comprises the steps of:
processing the band limited frequency response to produce a complex time domain signal according to the function
h(n)=1/NΣ_{k=0→(N-1)}H(ωₖ)e^{i2π(k/2N)n}=IDFT(2H,2N)
where h(n) is the complex time domain signal and H(ωₖ) is a reflection coefficient at frequency ωₖ (k=0,1 , . . . ,N−1); and
extracting a real portion of the complex time domain signal as the DTF signal.

4. The method as recited in claim 1 wherein the estimating step includes the steps of:
identifying reflection events from the DTF signal; and
performing the estimating step for data points from the DTF signal localized about each reflection event.

5. The method as recited in claim 4 wherein the identifying step comprises the step of user interactively defining the data points localized about each reflection event observed in the DTF signal.

6. The method as recited in claim 4 wherein the identifying step comprises the steps of:
determining a detection function for the DTF signal; and
locating data points localized about the reflection events when the detection function exceeds a predetermined threshold.

7. The method as recited in claims 4, 5 or 6 wherein the performing step comprises the step of applying least-square error criteria.

8. The method as recited in claims 1, 2 or 3 wherein the estimating step comprises the step of processing the DTF signal to obtain the impulse response according to the function
h_{DTF}(n)=l(n)−l(n)\hat{×}w(n)
where h_{DTF}(n) is the DTF signal, l(n) is the impulse response and w(n) is the window function
w(n)=sin(ω₀n/Fₛ)/πn
where ω₀ represents a starting frequency of the band limited frequency response and Fₛ represents a sampling frequency.

9. The method as recited in claim 8 wherein the estimating step further comprises the steps of:
identifying reflection events in the DTF signal; and
performing the DTF signal processing step for data points localized about each reflection event.

10. The method as recited in claim 9 wherein the identifying step comprises the step of user interactively defining the data points localized about each reflection event observed in the DTF signal.

11. The method as recited in claim 10 wherein the performing step comprises the step of applying least-square error criteria.

12. The method as recited in claim 9 wherein the identifying step comprises the steps of:
determining a detection function for the DTF signal; and
locating data points localized about the reflection events when the detection function exceeds a predetermined threshold.

13. The method as recited in claim 12 wherein the performing step comprises the step of applying least-square error criteria.

14. The method as recited in claims 1, 2, 3 or 4 further comprising the step of displaying the impulse response and step function response.

15. The method as recited in claim 7 further comprising the step of displaying the impulse response and step function response.
